(19) United States
(12) Patent Application Publication
(10) Pub. No.: US 2018/0062649 A1
(43) Pub. Date: Mar. 1, 2018

(54) CAPACITIVE INPUT PAD

(71) Applicant: Ford Global Technologies, LLC, Dearborn, MI (US)

(72) Inventors: Stuart C. Salter, White Lake, MI (US); Paul Kenneth Dellock, Northville, MI (US); Pietro Buttolo, Dearborn Heights, MI (US); Aaron Bradley Johnson, Allen Park, MI (US); Chester Stanislaus Walawender, Livonia, MI (US)

(73) Assignee: Ford Global Technologies, LLC

(21) Appl. No.: 15/251,372

(22) Filed: Aug. 30, 2016

(51) Int. Cl. H03K 17/96; B60R 25/23

(52) U.S. Cl. CPC H03K 17/9622; B60R 25/23; B60R 2325/40; H03K 2217/960785; H03K 2217/960755; H03K 2017/9613

(57) ABSTRACT

A vehicle capacitive key input pad assembly includes a pad comprising a region defining an illuminated character. The assembly also includes a first electrode having electrode fingers and extending at least partially around the illuminated character region, and a second electrode having electrode fingers and at least partially extending into the character region. One or more electrode fingers trace a portion of the illuminated character.

### FIELD OF THE INVENTION

The present invention generally relates to proximity sensor input devices and more particularly relates to capacitive input pads.

### BACKGROUND OF THE INVENTION

Automotive vehicles are commonly equipped with various user actuatable input devices for entering inputs to control devices or functions. For example, key pads are often provided on the vehicle body exterior to enable a user to enter a sequence of inputs as a code to actuate a door lock without a mechanical key or key fob. Conventional key pads employed on motor vehicles typically include mechanical switches actuatable by users. It would be desirable to provide for an enhanced key pad assembly that is economical and offers enhanced and reliable performance.

### SUMMARY OF THE INVENTION

According to one aspect of the present invention, a capacitive input pad assembly is provided. The capacitive input pad assembly includes a pad comprising a region defining an illuminated character. The assembly also includes a first electrode comprising a first plurality of electrode fingers and extending at least partially around the illuminated character region, and a second electrode comprising a second plurality of electrode fingers and at least partially extending into the character region.

According to another aspect of the present invention, a capacitive key input pad assembly is provided that includes a pad comprising a region defining an illuminated character. The assembly also includes a first electrode comprising a second plurality of electrode fingers and extending at least partially around the illuminated character region, and a second electrode comprising a second plurality of electrode fingers, wherein at least one of the first and second electrodes traces at least a portion of the illuminated character.

According to a further aspect of the present invention, a vehicle capacitive key pad assembly is provided that includes a pad comprising a region defining an illuminated character. The assembly also includes a first electrode extending at least partially around the illuminated character region and having a first plurality of electrode fingers. The assembly further includes a second electrode having a second plurality of electrode fingers and at least partially extending into the character region, wherein at least one of the first and second electrodes traces at least a portion of the illuminated character.

These and other aspects, objects, and features of the present invention will be understood and appreciated by those skilled in the art upon studying the following specification, claims, and appended drawings.

### BRIEF DESCRIPTION OF THE DRAWINGS

In the drawings:

FIG. 1 is a perspective view of a motor vehicle equipped with a capacitive input key pad assembly for controlling the door lock on the vehicle, according to one embodiment;

FIG. 2 is an enlarged view of section II of FIG. 1 further illustrating the capacitive input key pad assembly;

FIG. 3 is an exploded view of the capacitive input key pad assembly shown in FIG. 2;

FIG. 4 is a cross-sectional view of the capacitive input key pad assembly taken through line 4-4 of FIG. 2;

FIG. 5 is a front view of the capacitive input key pad assembly shown in FIG. 2;

FIG. 6 is a front view of the capacitive input key pad assembly with select layers removed;

FIG. 7 is an enlarged view of section VII of FIG. 6 further illustrating one of the capacitive input key pads and the electrode configuration; and

FIG. 8 is a block diagram of the capacitive key pad input assembly.

### DETAILED DESCRIPTION OF THE PREFERRED EMBODIMENTS

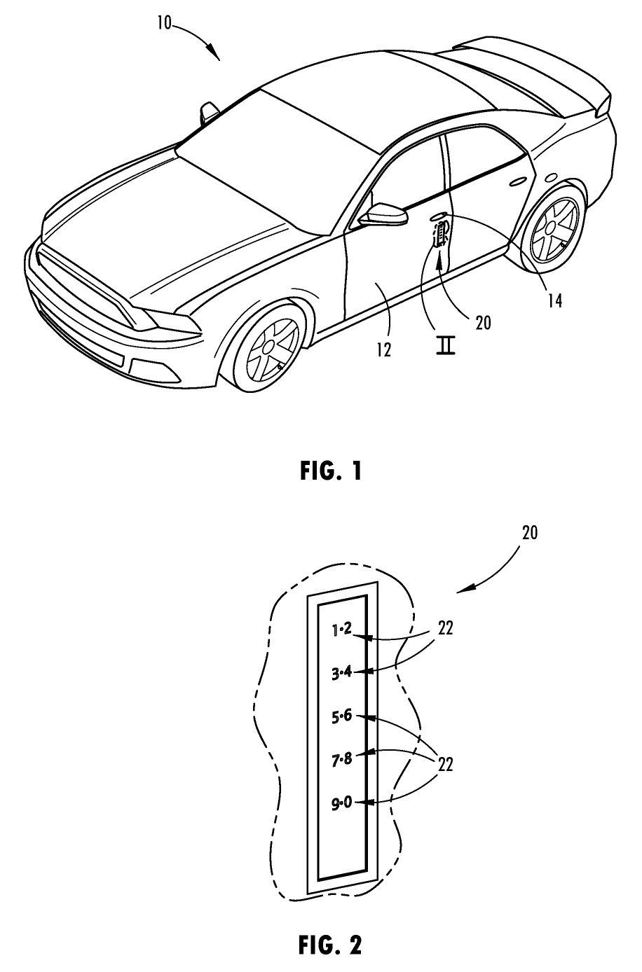

For purposes of description herein, the terms “upper,” “lower,” “right,” “left,” “rear,” “front,” “vertical,” “horizontal,” and derivatives thereof shall relate to the invention as oriented in FIG. 2. However, it is to be understood that the invention may assume various alternative orientations, except where expressly specified to the contrary. It is also to be understood that the specific devices and processes illustrated in the attached drawings, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

Referring to FIG. 1, a wheeled motored vehicle 10 is generally illustrated having a capacitive input pad assembly 20 shown configured as a vehicle door access key pad assembly that enables a person to enter a sequence of inputs to lock and unlock the vehicle doors, according to one embodiment. The vehicle 10 includes a passenger door 12 provided on the vehicle body and a door latch lock assembly 14 positioned on the door 12. The door latch lock assembly 14 may be actuatable by a person to unlatch and thereby open the door and other doors on the vehicle to gain access to the vehicle. It should be appreciated that a driver may actuate a door lock switch in the vehicle and may also be equipped with a key fob that may remotely lock and unlock the door latch lock assembly 14 of vehicle door 12. The capacitive input pad assembly 20 is configured with a plurality of user selectable input pads 22 (FIG. 2) to enable a person to input a code to lock and unlock the vehicle door 12 by entering a programed sequence of input characters (e.g., numbers) via pads 22 labelled with the identifier characters.

The input pad assembly 20 is illustrated further in FIG. 2 having the plurality of user selectable input pads 22 shown arranged vertically, according to one embodiment. The input pads 22 include lighted characters displayed on the front face, each defining a region upon which a user may touch the input pad 22 with a finger or come in close proximity therewith to provide an input selection. The characters shown include numerical characters one and two (1.2) for the first input pad, numerical characters three and four (3.4) for the second input pad, numerical characters five and six (5.6) for the third input pad, numerical characters seven and eight (7.8) for the fourth input pad, and numerical characters nine and zero (9.0) for the fifth input pad. It should be appreciated that other characters such as letters or symbols may be employed as input pad identifiers. Each of the input pads 22 has a capacitive sensor that senses contact or close proximity (e.g., 1 millimeter) of the user's finger with the pad and defines a binary switch output (on or off) indicative a user selection of that corresponding input pad.

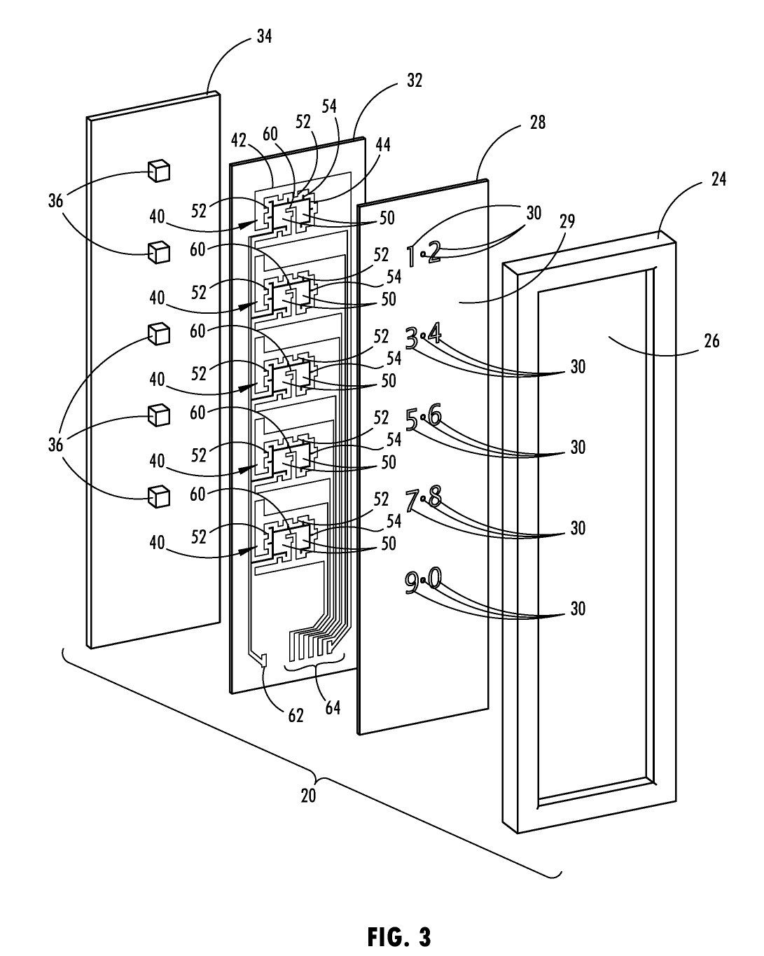

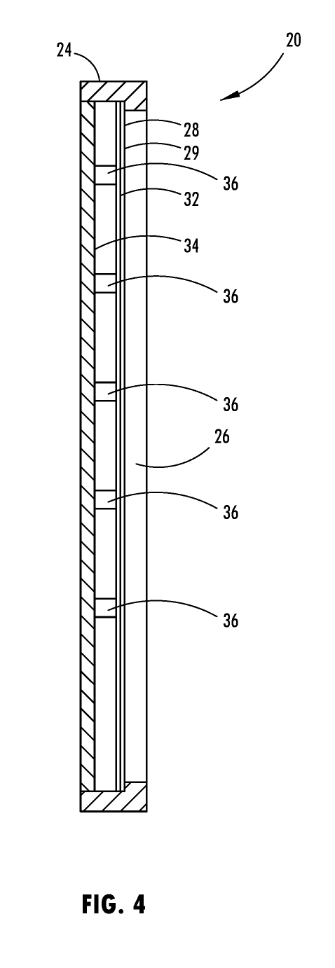

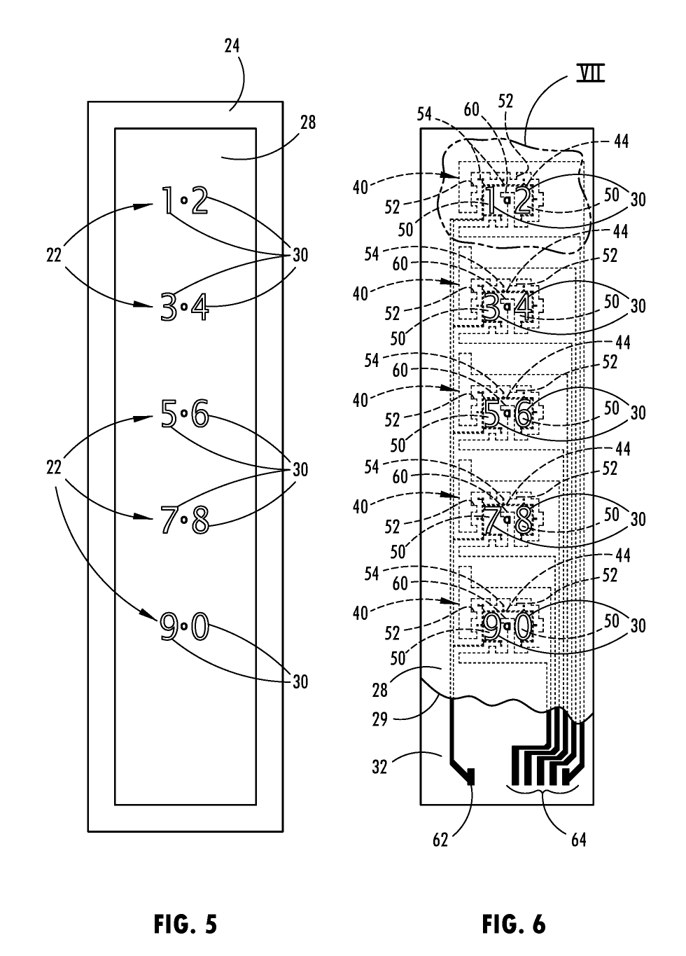

Referring to FIGS. 3 and 4, the capacitive key pad input assembly 20 is further illustrated having various components assembled in layers. The capacitive key pad input assembly 20 includes a front housing 24 generally defining a frame and an open window 26 therein. A character board 28 is disposed behind the frame 24 and fitted within the open window 26. The character board 28 includes a light transmissive medium and mask 29 that covers the front surface except at the characters 30 and defines the plurality of the identifiable characters 30 that are arranged on the key pad assembly in a position to illuminate with back light illumination. By providing a light transmissive medium and mask 29 defining the characters 30, light is able to penetrate through the characters 30 to be illuminated and viewed from the front side. The light transmissive medium may include a transparent window such as glass or a light bar, according to various embodiments. The light transmissive medium may be in the form of openings formed in the shape of the characters, according to another embodiment.

Disposed behind the character board 28 is a capacitive sensor circuit board 32 which includes a plurality of capacitive sensors 40 and the interconnecting electrode lead lines 62 and 64. The capacitive sensors 40 and electrical lead lines 62 and 64 may be formed of a printed conductive ink or indium tin oxide (ITO) which may be made of a visibly transparent ink, according to specific embodiments. The conductive elements of the capacitive sensors 40 and electrical lead lines 62 and 64 may be formed of copper such as flexible copper circuitry, according to another embodiment. The capacitive sensors 40 are formed of first and second electrodes each having electrode fingers which are generally aligned with the characters 30 on board 28. Each of the capacitive sensors 40 includes a character region 50 aligned with the characters 30.

The electrical lead lines 62 and 64 connect to the electrodes of each capacitive sensor 40 to transmit and receive signals. The electrical lead line 62 is shown connecting to the drive electrode of each of the capacitive sensors 40. The electrical lead line 62 has an input at the bottom terminal end which may connect to control circuitry that supplies a drive signal. The electrical lead lines 64 include respective lead lines that connect to respective receive electrodes of the capacitive sensors 40. Each capacitive sensors 40 thereby has its separate lead line 64 which connects or is coupled to control circuitry for processing the signals generated by the corresponding capacitive sensors 40.

Disposed behind capacitive sensor circuit board 32 is a lighting circuit board 34 which is shown having a plurality of light sources 36, which may each include a light emitting diode (LED), according to one embodiment. Each of the light sources 36 is aligned to back light one of the capacitive sensors 40 on the capacitive sensor circuit board 32 so that the light illuminates through the capacitive sensor circuit board 32 and through the characters 30 in character board 28 to be viewed from the front side. As such, each of the character regions 50 within the capacitive sensors 40 is transparent to light so as to allow light to transmit therethrough unimpeded and through the characters 30 for viewing from the front side.

As seen in FIG. 6, each of the capacitive sensors 40 includes a first electrode 42 and a second electrode 44. Each of the first and second electrodes 42 and 44 includes a plurality of conductive electrode fingers 52 and 54, respectively. As such, the first electrode 42 has a first electrode fingers 52 and the second pluralities of electrode 44 has a second plurality of electrode fingers 54. Each of the plurality of first and second electrode plurality of fingers 52 and 54 is generally positioned to be interdigitated or interlaced with the other of the first and second electrode fingers 52 and 54 to some degree to generate a capacitive activation field for sensing the presence of an object such as a user's hand. The first electrode 42 may be configured as a receive electrode and receives a sense signal, and the second electrode 44 may be configured as a drive electrode to receive a drive signal.

The capacitive sensors 40 each provide a capacitive sense activation field to sense contact or close proximity (e.g., within one mm) of a user (e.g., finger) in relation to the corresponding capacitive sensor. The capacitive sense activation field of each capacitive sensor 40 detects a user's finger which has electrical conductivity and dielectric properties that cause a change or disturbance in the capacitive sense activation field as should be evident to those skilled in the art. Each of the capacitive sensors 40 provides a sensed signal for a corresponding key pad indicative of a user input. A user may enter a sequence of user inputs on the key pads that match a programmed key code to lock or unlock one or more vehicle doors, according to one embodiment.

The capacitive sensors 40 each generally have a drive electrode 44 and a receive electrode 42, each having interdigitated fingers for generating a capacitive field. It should be appreciated that each of the capacitive sensors 40 may be formed by printed conductive ink or by assembling preformed conductive circuitries onto a substrate. According to one embodiment, the drive electrode 44 receives square wave drive signal pulses applied at voltage V_{I}. The receive electrode 42 has an output for generating an output voltage V_{O}. It should be appreciated that the electrodes 42 and 44 and electrode fingers 52 and 54 may be arranged in various configurations for generating the capacitive fields as the sense activation fields, according to various embodiments.

In the embodiment shown and described herein, the drive electrode 44 of each capacitive sensor 40 is supplied with input voltage V_{I} as square wave signal pulses having a charge pulse cycle sufficient to charge the receive electrode 42 to a desired voltage. The receive electrode 42 thereby serves as a measurement electrode. The adjacent sense activation fields generated by adjacent capacitive sensors may overlap slightly or overlap may not exist. When a user or operator, such as a user's finger enters a capacitive sense activation field, the corresponding capacitive sensor detects a disturbance caused by the finger to the activation field and determines whether the disturbance is sufficient to generate an input with the corresponding capacitive sensor. The disturbance of the activation field is detected by processing the charge pulse signal associated with the corresponding signal channel for that capacitive sensor. Each capacitive sensor 40 has its own dedicated signal channel generating a distinct charge pulse signal which may be processed individually.

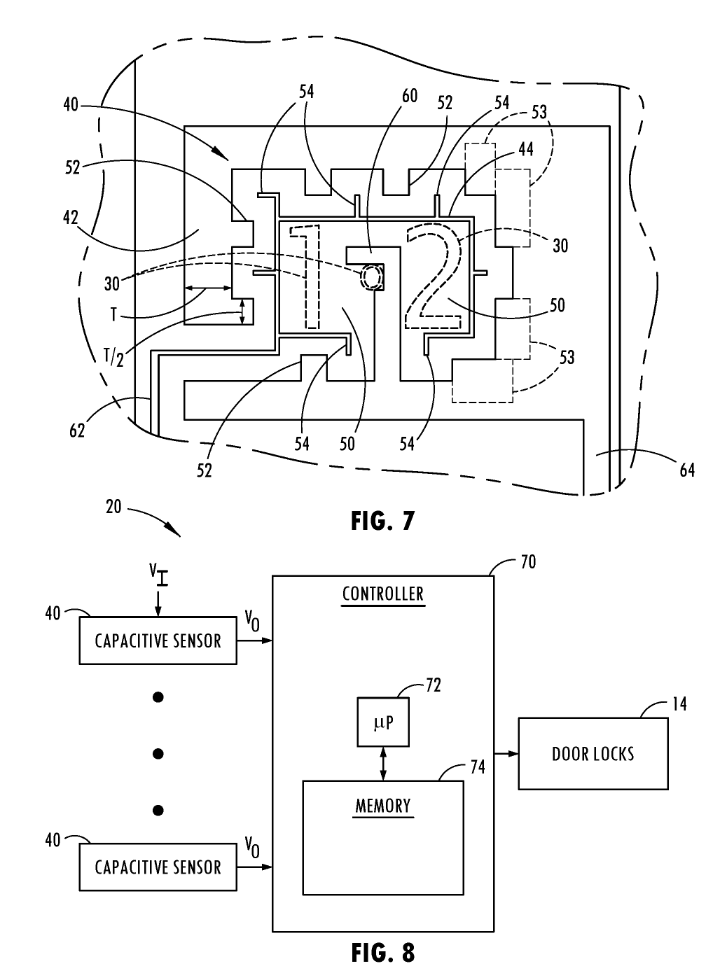

Referring to FIG. 8, the capacitive key pad input assembly 20 is illustrated according to one embodiment. The plurality of capacitive sensors 40 are shown providing respective inputs to a controller 70, such as a microcontroller. The controller 70 may include circuitry, such as a microprocessor 72 and memory 74. The control circuitry may include sense control circuitry processing the activation filed of each capacitive sensor to sense user activation by comparing the activation field signal to one or more thresholds pursuant to one or more routines. It should be appreciated that other analog and/or digital control circuitry may be employed to process each capacitive activation field, to determine user activation, and initiate an action. The controller 70 may employ a Q matrix acquisition method available by ATMEL®, according to one embodiment. Exemplary capacitive sensors are described in the Apr. 9, 2009, ATMEL® Touch Sensors Design Guide 10620 D-AT42-A4/09, the entire reference hereby being incorporated herein by reference.

The controller may include an analog to digital (A/D) comparator integrated within or coupled to the microprocessor 72 which may receive the voltage output V_{O} from each of the capacitive sensors, convert the analog signal to a digital signal, and provide a digital signal to the microprocessor 72. The controller 70 may include a pulse counter integrated within or coupled to the microprocessor 72 that counts the charge signal pulses that are applied to each drive electrode of each proximity sensor, performs a count of the pulses needed to charge the capacitor until the voltage output V_{O} reaches a more predetermined voltage, and provides the count to the microprocessor 72. The pulse count is indicative of the change in capacitance of the corresponding capacitive sensor. The controller 70 may provide a pulse width modulated signal to a pulse width modulated drive buffer to generate the square-wave pulse which is applied to each drive electrode of each capacitive sensor. The controller 70 may process the received signals and make a determination as to activation of one of the capacitive sensors. The controller 70 may further determine whether a sequence of user inputs matches a programmed code and unlock or lock the vehicle doors when the code is matched by the sequence of inputs.

The drive and receive electrodes 44 and 42 of each of the capacitive sensors 40 are further illustrated in FIGS. 6 and 7. The drive electrodes 44 receive a common drive input signal V_{I} on drive line 62. Each of the capacitive sensors 40 has an output line 64 for outputting the corresponding voltage V_{O}. The output lines 64 may be fed to a common interface and may be provided to the controller 70 via circuitry.

Referring to FIG. 7, one of the capacitive sensors 40 is further illustrated in more detail. The capacitive input pad assembly 20 includes input pad 22 comprising a character region 50 including one or more illuminated characters 30. The capacitive sensor 40 is shown having the receive electrode 42 generally formed extending at least partially around the illuminated character region 50. One or more characters 30 are generally overlaid within the character region 50 as indicia to identify the input key pad 22. The character region is the region in which the illuminated characters are located. The first or receive electrode 42 includes a first plurality of electrode fingers 52 which generally extend radially inward from the main portion of the receive electrode 42 and towards the drive electrode 44. One of the receive electrode fingers 60 is shown extending within the character region 50 such that the electrode finger 60 extend vertical and horizontal in an approximate L-shape within the character region 50. In doing so, the electrode finger 60 traces at least a portion of the character “.” between characters “1” and “2” within the character region. By tracing at least a portion of the character, the electrode finger 60 is in close proximity to the character 30, preferably within 1 millimeter. This provides for an enhanced capacitive signal at the character region and input pad 22.

The receive electrode 42 has a base portion from which the fingers 52 extend. The base portion has a width shown by dimension (T). The first plurality of electrode fingers 52 of the receive electrode 42 may have a width of about one-half the width of the base (T/2). The width of the first plurality of electrode fingers 52 may be at least one-half the width of the base (T/2), according to one embodiment. According to one example, the width of the base portion of electrode 42 may be approximately 2.4 millimeters, while the width of the first plurality of electrode fingers may be approximately 1.2 millimeters.

The second or drive electrode 44 is formed radially inward within the receive electrode 42 and extends at least partially into the illuminated character region 50. The drive electrode 44 has a base portion which enters from lead line 62 within an open region of the receive electrode 42 which may have a spacing of approximately 2.2 millimeters, according to one example. The drive electrode 44 has a second plurality of outward extending electrode fingers 54 extending outward from the base portion and towards the receive electrode 42. The second plurality of outward extending electrode fingers 54 may be interlaced or interdigitated with the first plurality of inward extending electrode fingers 52 of the receive electrode 42. The second plurality of electrode fingers 52 may have a width of approximately 0.15 millimeter which is substantially less than the width of the first plurality of electrode fingers, according to one embodiment. The drive electrode 44 extends around the character region 50 and traces at least a portion of one or more of the characters 30 within the illuminated character region 50. By tracing at least a portion of one or more of the characters, the drive electrode 44 is in close proximity to the character(s), preferably within 1.0 millimeter. Thus, the drive electrode 44 and electrode fingers 54 boarder on the characters and are formed very close or proximate to one or more of the characters 30 so as to provide for an enhanced capacitive signal coupling with the electrode fingers 52 of the receive electrode 42.

In the upper right and lower right corners of the capacitive sensor 40, the corner regions may include L-shaped electrode fingers 53. The L-shaped fingers 52B may increase the capacitive signal in these corner regions by increasing the electrode area and may achieve enhanced separation from adjacent input pads.

While the drive electrode 44 is shown formed within the receive electrode 42, it should be appreciative that the electrodes may be switched around such that the drive electrode 44 is on the outside and the receive electrode 42 is on the inside. It should be appreciative that other characters and configurations of the electrodes and electrode fingers may be used.

The capacitive input pad assembly 20 advantageously may be formed with flex circuitry, such as a copper flex circuit to be utilized without the need for clear conductive ink. The capacitive input pad assembly 20 may be applied to various types and sizes of input pads and characters. The capacitive input pad assembly 20 advantageously maximizes the interlacing between adjacent electrode fingers to achieve enhanced signal sensitive and noise rejection for a given pad area.

It is to be understood that variations and modifications can be made on the aforementioned structure without departing from the concepts of the present invention, and further it is to be understood that such concepts are intended to be covered by the following claims unless these claims by their language expressly state otherwise.

1. A capacitive input pad assembly comprising:
a pad comprising a region defining an illuminated character;
a first electrode comprising a first plurality of electrode fingers and extending at least partially around the illuminated character region; and
a second electrode comprising a second plurality of electrode fingers and at least partially extending into the character region.

2. The assembly of claim 1, wherein at least one of the first and second electrodes traces at least a portion of the illuminated character.

3. The assembly of claim 2, wherein at least one of the second electrode fingers extends into the character region and traces the portion of the illuminated character.

4. The assembly of claim 1, further comprising a light source located behind the character region for back lighting the character region.

5. The assembly of claim 1, wherein the first plurality of electrode fingers interlace with the second plurality of electrode fingers.

6. The assembly of claim 1, wherein the first electrode has a width at least about twice a width of the second electrode.

7. The assembly of claim 1, wherein the pad assembly is employed on a vehicle.

8. The assembly of claim 7, wherein the pad assembly is employed as a key pad assembly to control operation of a door lock to lock or unlock a vehicle door.

9. A capacitive key input pad assembly comprising:
a pad comprising a region defining an illuminated character;
a first electrode comprising a first plurality of electrode fingers and extending at least partially around the illuminated character region; and
a second electrode comprising a second plurality of electrode fingers, wherein at least one of the first and second electrodes traces at least a portion of the illuminated character.

10. The assembly of claim 9, wherein at least one of the second electrode fingers traces the portion of the illuminated character.

11. The assembly of claim 9, wherein the second electrode at least partially extends into the character region.

12. The assembly of claim 9, further comprising a light source for back lighting the character region.

13. The assembly of claim 9, wherein the first and second electrode fingers are interdigitated.

14. The assembly of claim 9, wherein the first electrode has a width at least twice a width of the second electrode.

15. The assembly of claim 9, wherein the pad assembly is employed on a vehicle.

16. The assembly of claim 15, wherein the pad assembly is employed as a key pad assembly to control operation of a door lock to lock or unlock a vehicle door.

17. A vehicle capacitive key pad assembly comprising:
a pad comprising a region defining an illuminated character;
a first electrode extending at least partially around the illuminated character region and having a first plurality of electrode fingers; and
a second electrode having a second plurality of electrode fingers and at least partially extending into the character region, wherein at least one of the first and second electrodes traces at least a portion of the illuminated character.

18. The assembly of claim 17, wherein the first plurality of electrode fingers interlace with the second plurality of electrode fingers.

19. The assembly of claim 17, wherein at least one of the second plurality of electrode fingers extends into the character region.

20. The assembly of claim 17, wherein the key pad assembly is employed to control operation of a door lock to lock or unlock a vehicle door.
